(19) United States
(12) Patent Application Publication
(10) Pub. No.: US 2024/0321606 A1
(43) Pub. Date: Sep. 26, 2024

(54) HEAT STAMP AND METHOD FOR RELEASING PROTECTIVE TAPE USING HEAT STAMP

(71) Applicants: Kabushiki Kaisha Toshiba, Tokyo (JP); Toshiba Electronic Devices & Storage Corporation, Tokyo (JP)

(72) Inventor: Shinsuke KOZUMI, Kanazawa Ishikawa (JP)

(21) Appl. No.: 18/495,699

(22) Filed: Oct. 26, 2023

(30) Foreign Application Priority Data
Mar. 24, 2023 (JP) 2023-047913

(51) Int. Cl. H01L 21/67; B32B 43/00

(52) U.S. Cl. CPC H01L 21/67132; B32B 43/006

(57) ABSTRACT

A heat stamp according an embodiment is the heat stamp used for releasing a protective tape from a substrate, the substrate including a first substrate surface, a second substrate surface provided opposite to the first substrate surface, the protective tape pasted on the second substrate surface, and a release tape having a strip-like configuration, the release tape being pasted on the protective tape from above a fifth end of the second substrate surface to above a sixth end of the second substrate surface, the fifth end and the sixth end facing each other across the center of the second substrate surface, the heat stamp including: a bottom surface having a first side, the first side being provided on a side of a releasing direction of the release tape, the releasing direction being parallel to a longitudinal direction of the strip-like configuration.

### CROSS-REFERENCE TO RELATED APPLICATION

This application is based upon and claims the benefit of priority from Japanese Patent Application No. 2023-047913, filed on Mar. 24, 2023, the entire contents of which are incorporated herein by reference.

### FIELD

Embodiments described herein relate generally to a heat stamp and a method for releasing a protective tape using the heat stamp.

### BACKGROUND

Semiconductor devices such as a MOSFET (Metal Oxide Semiconductor Field Effect Transistor) are used in applications for power conversion.

In manufacturing such a semiconductor device, a protective tape such as a back grind tape (BG tape) is pasted on a substrate surface of a wafer (substrate). When the protective tape is released, a release tape is used. Specifically, the release tape is pasted on the protective tape, and the release tape is released, thereby the protective tape is released together with the release tape from the substrate surface.

### BRIEF DESCRIPTION OF THE DRAWINGS

FIG. 1A-B are schematic diagrams showing the substrate, the protective tape, and the release tape according to a first embodiment.

FIG. 2 is a schematic diagram of a protective tape releasing device using the heat stamp according to the first embodiment.

FIG. 3 is a schematic diagram of a main part of the protective tape releasing device using the heat stamp according to another aspect of the first embodiment.

FIG. 4 is a schematic bottom view of the bottom surface of the heat stamp according to the first embodiment.

FIGS. 5A-D are schematic bottom views of the bottom surface of the heat stamp according to another aspect of the first embodiment.

FIGS. 6A-C are schematic bottom views of the bottom surface of the heat stamp according to another aspect of the first embodiment.

FIG. 7 is a schematic diagram for explaining the method for releasing the protective tape using the heat stamp according to the first embodiment.

FIG. 8 is a schematic diagram for explaining the method for releasing the protective tape using the heat stamp according to the first embodiment.

FIG. 9 is a schematic diagram for explaining the method for releasing the protective tape using the heat stamp according to the first embodiment.

FIG. 10 is a schematic diagram for explaining the method for releasing the protective tape using the heat stamp according to the first embodiment.

FIG. 11 is a flow chart of the method for releasing the protective tape using the heat stamp according to the first embodiment.

FIG. 12 is a schematic diagram of the heat stamp according to a comparative embodiment of the first embodiment.

FIG. 13 is a schematic diagram of the method for releasing the protective tape using the heat stamp according to the comparative embodiment of the first embodiment.

FIG. 14 is a schematic diagram of the method for releasing the protective tape using the heat stamp according to the comparative embodiment of the first embodiment.

FIG. 15 is a schematic diagram for explaining the method for releasing the protective tape using the heat stamp according to the first embodiment.

FIG. 16 is a schematic bottom diagram of the bottom surface of the heat stamp according to a second embodiment.

FIG. 17 is a schematic bottom diagram of the bottom surface of the heat stamp according to another aspect of the second embodiment.

### DETAILED DESCRIPTION

A heat stamp according to an embodiment is the heat stamp used for releasing a protective tape from a substrate, the substrate including a first substrate surface, a second substrate surface provided opposite to the first substrate surface, the protective tape pasted on the second substrate surface, and a release tape having a strip-like configuration, the release tape being pasted on the protective tape from above a fifth end of the second substrate surface to above a sixth end of the second substrate surface, the fifth end and the sixth end facing each other across the center of the second substrate surface, the heat stamp including: a bottom surface having a first side, the first side being provided on a side of a releasing direction of the release tape, the releasing direction being parallel to a longitudinal direction of the strip-like configuration, and the releasing direction being from above the fifth end of the second substrate surface to above the sixth end of the second substrate surface, wherein, when the bottom surface is pressed on the release tape, the first side has a protrusion protruding in the releasing direction of the release tape, the protrusion is provided between a first end of the first side and a second end of the first side, and the first end and the second end are provided separately from each other in a direction intersecting the releasing direction.

Hereinafter, embodiments of the present disclosure will be described with reference to the drawings. Note that in the following description, the same members and the like are denoted by the same reference numerals, and description of members and the like once described is appropriately omitted.

In this specification, in order to illustrate the positional relationship of parts and the like, the upward direction of the drawings may be referred to as “upper”, and the downward direction of the drawings may be referred to as “lower”. Here, the terms “up” and “down” do not necessarily indicate a relationship with the direction of gravity.

### First Embodiment

A heat stamp according to the present embodiment is the heat stamp used for releasing a protective tape from a substrate, the substrate including a first substrate surface, a second substrate surface provided opposite to the first substrate surface, the protective tape pasted on the second substrate surface, and a release tape having a strip-like configuration, the release tape being pasted on the protective tape from above a fifth end of the second substrate surface to above a sixth end of the second substrate surface, the fifth end and the sixth end facing each other across the center of the second substrate surface, the heat stamp including: a bottom surface having a first side, the first side being provided on a side of a releasing direction of the release tape, the releasing direction being parallel to a longitudinal direction of the strip-like configuration, and the releasing direction being from above the fifth end of the second substrate surface to above the sixth end of the second substrate surface, wherein, when the bottom surface is pressed on the release tape, the first side has a protrusion protruding in the releasing direction of the release tape, the protrusion is provided between a first end of the first side and a second end of the first side, and the first end and the second end are provided separately from each other in a direction intersecting the releasing direction.

A method for releasing the protective tape using the heat stamp according to the present embodiment includes: a step of heating the heat stamp; a step of heating a part of the release tape located above the fifth end of the second substrate surface by using the heat stamp; a step of releasing the release tape from the part of the release tape located above the fifth end of the second substrate surface by moving a roller from above the fifth end of the second substrate surface, so as to maintain a constant distance between the roller and the substrate; and a step of releasing the release tape and the protective tape from the second substrate surface.

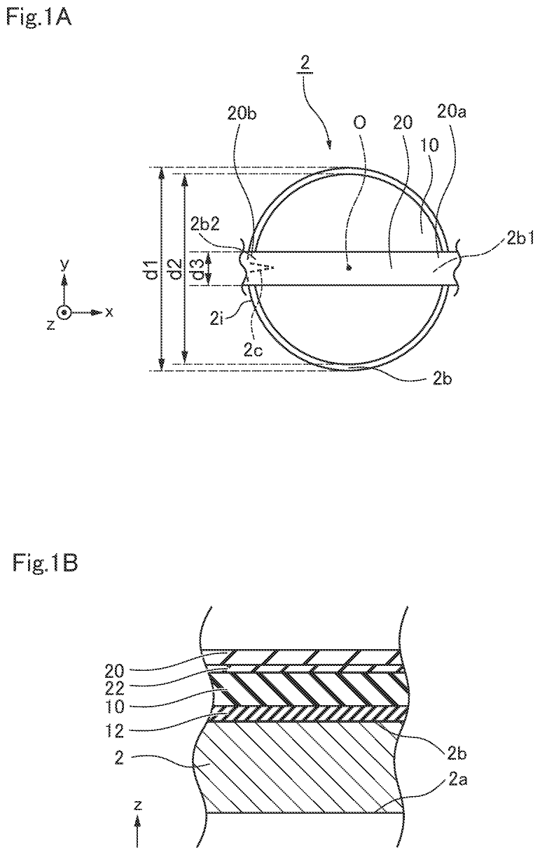

FIGS. 1A-B are schematic diagrams showing the substrate 2, the protective tape 10, and the release tape 20 of the present embodiment. FIG. 1A is a schematic top view of the substrate 2, the protective tape 10, and the release tape 20 of the present embodiment. FIG. 1B is a schematic cross-sectional view of a part of the substrate 2, the protective tape 10, and the release tape 20 of the present embodiment.

The substrate 2 includes a semiconducting material. Here, the semiconductive material is, for example, Si (silicon), SiC (silicon carbide), GaAs (gallium arsenide), or GaN (gallium nitride), but is not limited thereto. The substrate 2 is, for example, a substrate on which devices such as the MOSFET (Metal Oxide Semiconductor Field Effect Transistor) or an IGBT (Insulated Gate Bipolar Transistor) are formed. The heat stamp and the method for releasing the protective tape using the heat stamp of the present embodiment are used in a step of singulating the substrate 2 by dicing or the like and manufacturing the semiconductor device having the devices mentioned above. The semiconductor device of the present embodiment is, for example, a semiconductor chip.

The substrate 2 has a diameter d1. The substrate 2 has a first substrate surface 2a, and a second substrate surface 2b facing the first substrate surface 2a and provided above the first substrate surface 2a. In FIG. 1A, the center O of the second substrate surface 2b is shown together.

Here, an X-direction, a Y-direction perpendicular to the X-direction, and a Z-direction intersecting perpendicularly to the X-direction and the Y-direction are defined. It is assumed that first substrate surface 2a and the second substrate surface 2b are provided parallel to the XY plane.

The protective tape 10 is provided on the second substrate surface 2b. The protective tape 10 has the first adhesive layer 12. The protective tape 10 is pasted on the second substrate surface 2b by the first adhesive layer 12. When the semiconductor devices such as the MOSFETs, the IGBTs. and the like, are formed on the substrate 2, for on-resistance reduction, reducing the film thickness of the substrate 2 by grinding the first substrate surface 2a and thus reducing the on-resistance are performed. At this time, the protective tape 10 is used to protect the circuit patterns of the MOSFETs. IGBTs. and the like, which are formed on the second substrate surface 2b. The protective tape 10 is, for example, a back grinding tape. Further, the protective tape 10 is used for protecting the substrate 2 during the flow in the post-process. The heat stamp and the method for releasing the protective tape using the heat stamp of the present embodiment are used for releasing the protective tape 10 mentioned above.

Incidentally, the protective tape 10 may be pasted on the ground substrate surface. For example, consider the substrate 2 having the first substrate surface 2a on which circuit patterns of the MOSFETs or the IGBTs are formed and the second substrate surface 2b which is ground and thus the film thickness of the substrate 2 is reduced. In such cases, the protective tape 10 may be pasted on the second substrate surface 2b. The heat stamp and the method for releasing the protective tape using the heat stamp of the present embodiment are preferably used for releasing the protective tape 10 pasted on the ground second substrate 2b.

Further, the protective tape 10 may be pasted on the substrate surface which does not have the circuit patterns of the MOSFETs or the IGBTs and is not ground. For example, consider the substrate 2 having the first substrate surface on which the circuit patterns of the MOSFETs and the IGBTs are formed, and the second substrate surface 2b which is not ground. In such cases, the protective tape 10 may be pasted on the second substrate surface 2b. The heat stamp and the method for releasing the protective tape using the heat stamp of the present embodiment are preferably used for releasing the protective tape 10 pasted on the second substrate 2b which has no MOSFET or IGBT circuit patterns and is not ground.

Hereinafter, explanation will be given by assuming that the first substrate surface 2a is ground, and the circuit patterns of the MOSFETs and the IGBTs are formed on the second substrate surface 2b.

In FIG. 1A, the diameter d2 of the protective tape 10 is shorter than the diameter d1 of the substrate 2. However, the diameter d2 of the protective tape 10 may be longer than the diameter d1 of the substrate 2.

The release tape 20 is provided on the protective tape 10. The release tape 20 has, for example, a strip-like configuration and has a width d3 that is shorter than the diameter d1 of the substrate 2 and shorter than the diameter d2 of the protective tape 10. It should be noted that the width d3 of the release tape may be longer than the diametric d1 of the substrate 2. The release tape 20 is pasted on the protective tape 10 from above a fifth end 2b1 to above a sixth end 2b2 of the second substrate surface 2b across the second substrate surface 2b. The fifth end 2b1 and the sixth end 2b2 face each other across the center O of the second substrate surface 2b. The release tape 20 has a second adhesive layer 22. Then, the release tape 20 is pasted on the protective tape 10 by the second adhesive layer 22. The release tape 20 includes a third end 20a and a fourth end 20b. Note that the release tape 20 may have portions further extended from the third end 20a and the fourth end 20b, respectively. The release tape 20 is used to release the protective tape 10 from the second substrate surface 2b. The releasing direction of the release tape 20 is parallel to the longitudinal direction of the strip-like configuration. The releasing direction of the release tape 20 is from above the fifth end 2b1 of the second substrate surface 2b to above the sixth end 2b2 of the second substrate surface 2b.

Note that, for example, the protective tape 10 may further has an adhesive layer (not shown) which is adhered to the second adhesive layer 22.

The notch 2c of the substrate 2 is provided, for example, on the upper side of the drawing of FIG. 1A. However, the notch 2c may be provided, for example, on the lower side of the drawing, the left side of the drawing, or the right side of the drawing of FIG. 1A. Further, the notch 2c may not be provided. Further, instead of the notch 2c, an orientation flat may be provided.

Note that the substrate end 2i of the substrate 2 is also shown in FIG. 1A.

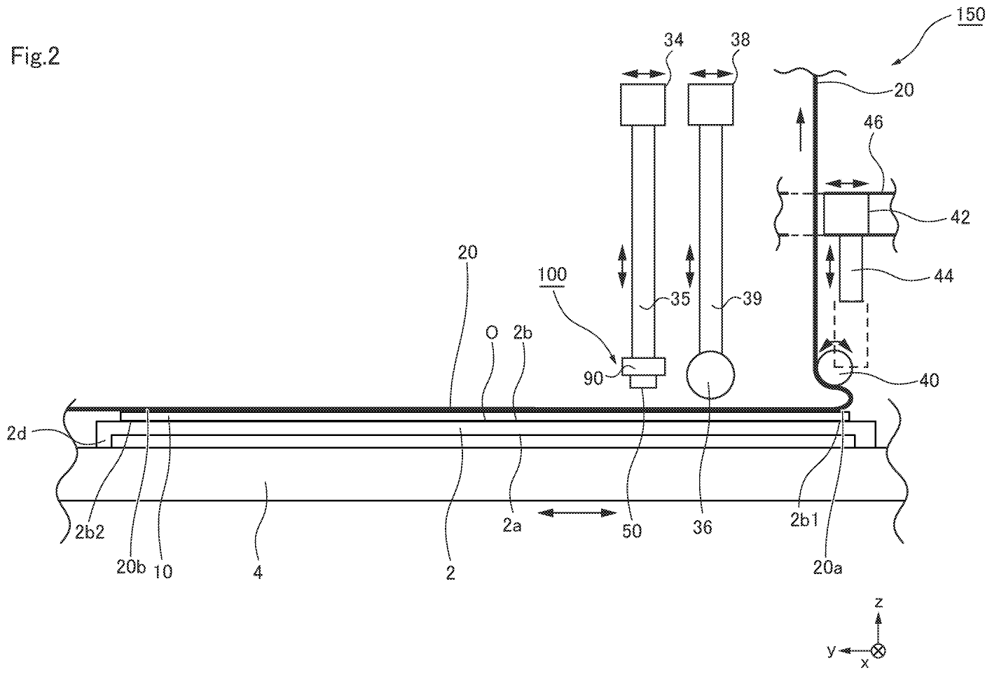

FIG. 2 is a schematic diagram of a protective tape releasing device 150 using the heat stamp according to the first embodiment.

Note that the illustrations of the first adhesive layer 12 and the second adhesive layer 22 are omitted.

Here, a case is explained where the protective tape 10, pasted on the second substrate surface 2b of the substrate 2, is released using the release tape 20 and the substrate 2 has been thinned by back-grinding. The first substrate surface 2a of the substrate 2 is provided with a ring protrusion 2d for maintaining the strength of the substrate 2 even when the substrate 2 is thinned. Note that the protective tape releasing device 150 using the heat stamp of the present embodiment is preferably applicable to the substrate 2 which is not thinned and does not have the ring protrusion 2d. Furthermore, the protective tape releasing device 150 using the heat stamp of the present embodiment is preferably applicable to the thinned the substrate 2 in which back surface grinding is performed on the entire surface of the first substrate surface 2a so that the first substrate surface 2a does not have the ring protrusion 2d.

Hereinafter, the releasing direction of the release tape 20 and the protective tape 10 is described as being the Y-direction.

A stage 4 is a stage on which the substrate 2 is placed. For example, the stage 4 is movable in the X-direction, the −X-direction, the Y-direction, and −Y-direction while the substrate 2 is held by a vacuum-suction device (not shown) or the like.

Here, the Z-direction is, for example, the opposite direction in the vertical direction. The stage 4 holds the first substrate surface 2a and the second substrate surface 2b horizontally.

A release roller 40 (an exemplary roller) is provided above the substrate 2. The release roller 40 is a roller for folding and releasing the release tape 20 when the release tape 20 is released from the third end 20a. The release roller 40 is rotatable in YZ plane. The release roller 40 is vertically movable, for example, by a cylinder 44 connected to the release roller 40. Further, for example, the cylinder 44 is movable above the substrate 2 in the Y-direction using a slider 42 provided in a rail 46. Accordingly, the release roller 40 is movable in the Y-direction on the substrate 2. Meanwhile, the means for enabling the release the roller 40 to move in the up-down direction and the Y-direction is not limited to those described above.

A paste roller 36 is provided above the substrate 2. The paste roller 36 is for pasting the release tape 20 on the protective tape 10 by pressing. The paste roller 36 is movable in the up-down direction and the Y-direction by, for example, a cylinder 39 connected to the paste roller 36 and a slider 38 connected to the cylinder 39.

The heat stamp 100 is provided above the substrate 2. The heat stamp 100 includes a heating device 90. The heating device 90 is, for example, a heater. The bottom surface 50 of the heat stamp 100 is heated by the heating device 90. The bottom surface 50 contacts the third end 20a of the release tape 20 pasted on the protective tape 10. Accordingly, the third end 20a of the release tape 20 is heated. Upon heating, the release tape 20 is more firmly pasted on the protective tape 10. The heater 32 is movable in the up-down direction and the Y-direction by, for example, a cylinder 35 connected to the heat stamp 100 and a slider 34 connected to the cylinder 35. Note that the bottom surface 50 may touch a location other than the third end 20a of the release tape 20.

Note that, for example, a winding roller (not shown) or the like is used to wind the release tape 20 and the protective tape 10 released using the release roller 40.

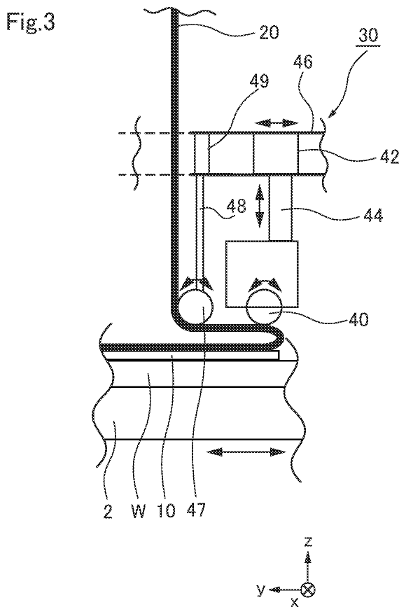

FIG. 3 is the schematic diagram of the main part of the protective tape releasing device using the heat stamp according to another aspect of the first embodiment. Here, in addition to the release roller 40, a fold-back roller 47 is provided. The release tape 20 released by the release roller 40 may be folded upward by the fold-back roller 47. Incidentally, for example, the fold-back roller 47 is movable in the up-down direction and the Y-direction by a cylinder 48 connected to the fold-back roller 47 and a slider 49 connected to the cylinder 48. The release roller 40 and the fold-back roller 47 in FIG. 3 are exemplary the roller.

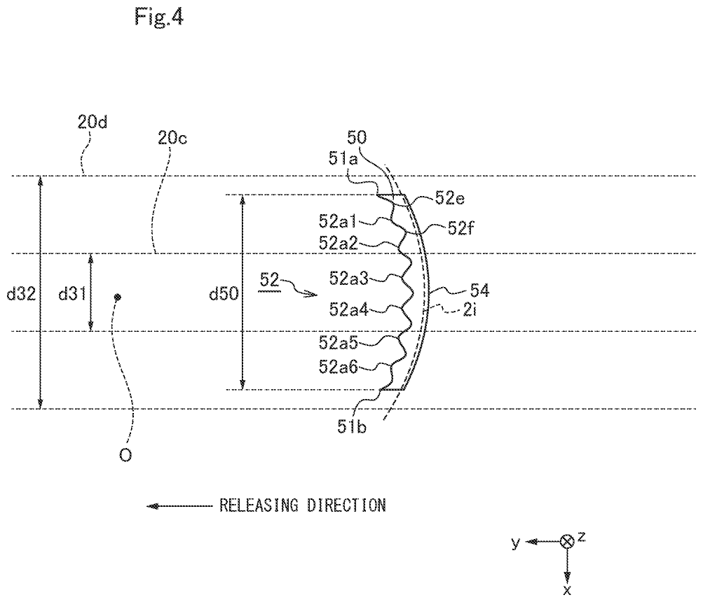

FIG. 4 is the schematic bottom view of the bottom surface of the heat stamp according to the first embodiment. In FIG. 4, the release tape 20c having a width d31 and the release tape 20d having a width d32 are shown. The length of the width d32 is longer than the length of the width d31. In addition, in FIG. 4, the center O of the second substrate surface 2b, the substrate end 2i of the substrate 2, and the release tape 20c are shown together. The bottom surface 50 is arranged parallel to the second substrate surface 2b.

The bottom surface 50 has a first side 52 provided on the side of the releasing direction of the release tape (Y-direction) and a second side 54 provided on the side of a direction opposite to the releasing direction of the release tape 20 (−Y-direction). The second side 54 is provided on the opposite side of the first side 52.

The first side 52 has a protrusion 52a1, a protrusion 52a2, a protrusion 52a3, a protrusion 52a4, a protrusion 52a5, and a protrusion 52a6 protruding in the releasing direction of the release tape 20 when the bottom surface 50 is pressed on the release tape 20. The protrusion 52a1, the protrusion 52a2, the protrusion 52a3, the protrusion 52a4, the protrusion 52a5, and the protrusion 52a6 are provided between the first end 51a and the second end 52b of the first side 52. The first end 51a and the second end 52b are provided separately from each other in a direction intersecting the releasing direction. The X-direction is an example of the direction intersecting the releasing direction. Here, in FIG. 4, six protrusions 52a are illustrated. The number of the protrusions 52a may be one. However, it is more preferable that a plurality of the protrusions 52a are provided. Here, the protrusion 52a will be described using the protrusion 52a1 as an example. The protrusion 52a1 is located between the first portion 52e of the first side 52 and the second portion 52f of the first side 52. The protrusion 52a1 is located on the side of the releasing direction than the first portion 52e and the second portion 52f.

Further, the first side 52 preferably has the protrusion 52a protruding in the releasing direction and the first side 52 is curved in a direction opposite to the releasing direction.

The first side 52 shown in FIG. 4 has a wavy configuration.

The shape of the second side 54 is, for example, curved in a direction opposite to the releasing direction.

The shape of the second side 54 is, for example, along the shape of the substrate end 2i of the substrate 2 in the vicinity of the third end 20a of the release tape.

Note that the shapes of the second side 54 are not limited to those described above.

Regarding the relationship between the width d31 of the release tape 20 in the X-direction and the width d50 of the bottom surface 50 in the X-direction, the width d50 of the bottom surface in the X-direction may be wider than the width d31 of the release tape 20c in the X-direction, as shown in the release tape 20c. In addition, as shown in the release tape 20d, the width d50 of the bottom surface in the X-direction may be narrower than the width d32 of the release tape 20d in the X-direction.

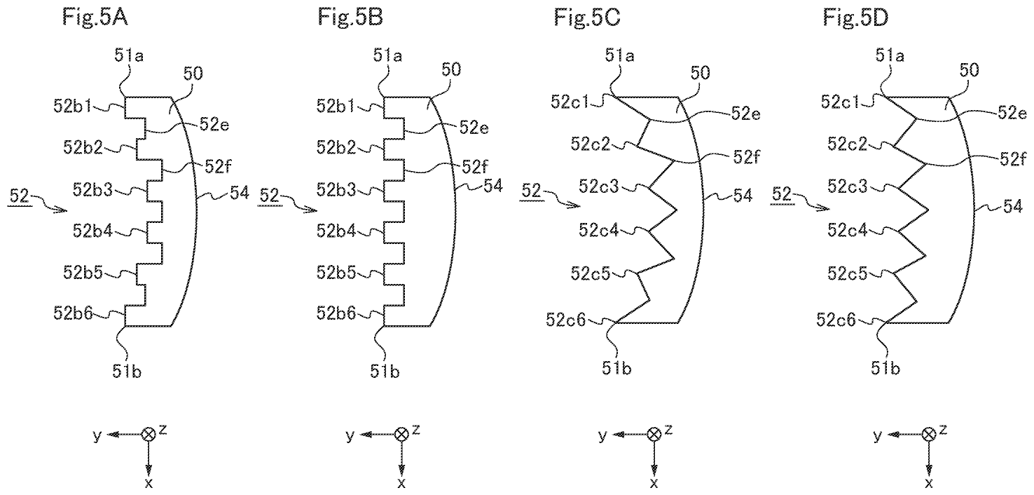

FIGS. 5A-D are schematic bottom views of the bottom surface of the heat stamp according to another aspect of the present embodiment.

FIGS. 5A-B show that the first side 52 of the bottom surface 50 has a protrusion 52b1, a protrusion 52b2, a protrusion 52b3, a protrusion 52b4, a protrusion 5265, and a protrusion 52b6 between the first end 51a and the second end 51b. The first side 52 of the bottom surface 50 shown in FIGS. 5A-B has a rectangular wave shape.

In the case of the first side 52 of the bottom surface 50 shown in FIG. 5A, the protrusion 52b2 and the protrusion 5265 protrude toward the releasing direction more than the protrusion 52b3 and the protrusion 52b4. The protrusion 52b1 protrudes toward the releasing direction more than the protrusion 52b2. The protrusion 52b6 protrudes toward the releasing direction more than the protrusion 52b5.

In the case of the first side 52 of the bottom surface 50 shown in FIG. 5B, the protrusion 52b1, the protrusion 52b2, the protrusion 52b3, the protrusion 52b4, the protrusion 5265, and the protrusion 52b6 are aligned in the X-direction.

Both of the bottom surface 50 of FIG. 5A and the bottom surface 50 of FIG. 5B are preferably used as the bottom surface 50 of the present embodiment. However, as shown in FIG. 5A, it is more preferable that the protrusion 52b2 and the protrusion 52b5 protrude toward the releasing direction more than the protrusion 52b3 and the protrusion 52b4. This is to facilitate the release of the protective tape 10 from above the fifth end 2b1 of the second substrate surface 2b by the arrangement of the protrusion 52b along the substrate edge 2i of the substrate 2.

FIGS. 5C-D show that the first side 52 of the bottom surface 50 has a vertex 52c1, a vertex 52c2, a vertex 52c3, a vertex 52c4, a vertex 52c5 and a vertex 52c6. Here, the vertex 52c1 is the first end 51a. The vertex 52c6 is the second end 51b. The first side 52 of the bottom surface 50 shown in FIGS. 5C-D has the form of a sawtooth wave-like shape. Note that the vertex is an exemplary the protrusion.

In the case of the first side 52 of the bottom surface 50 shown in FIG. 5C, the vertex 52c2 and the vertex 52c5 protrude toward the releasing direction more than the vertex 52c3 and the vertex 52c4. The vertex 52c1 protrudes toward the releasing direction more than the vertex 52c2. The vertex 52c6 protrudes toward the releasing direction more than the vertex 52c5.

In the case of the first side 52 of the bottom surface 50 shown in FIG. 5D, the vertex 52c1, the vertex 52c2, the vertex 52c3, the vertex 52c4, the vertex 5205 and the vertex 52c6 are aligned in the X-direction.

Both of the bottom surface 50 of FIG. 5C and the bottom surface 50 of FIG. 5D are preferably used as the bottom surface 50 of the present embodiment. However, as shown in FIG. 5C, it is more preferable that the vertex 52c2 and the vertex 52c5 protrude toward the releasing direction more than the vertex 52c3 and the vertex 52c4. This is to facilitate the release of the protective tape 10 from above the fifth end 2b1 of the second substrate surface 2b by the arrangement of the vertex 52c along the substrate edge 2i of the substrate 2.

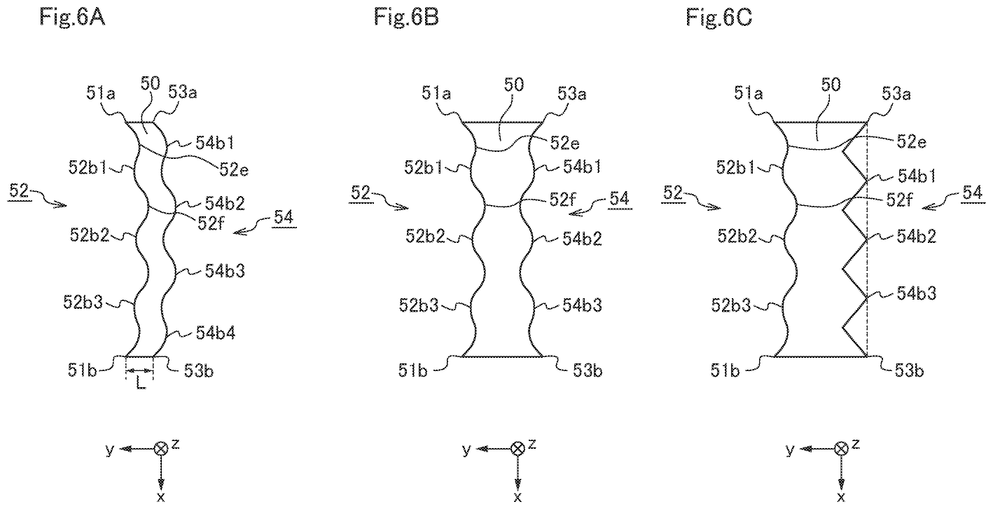

FIGS. 6A-C are schematic bottom views of the bottom surface of the heat stamp according to another aspect of the first embodiment.

In the case of the bottom surface 50 shown in FIG. 6A, the second side 54 has the protrusion 54b1, the protrusion 54b2, the protrusion 54b3, and the protrusion 54b4 protruding in a direction opposite to the releasing direction of the release tape 20 between an end 53a and an end 53b, and the end 53a and the end 53b are provided in a direction intersecting the releasing direction of the release tape 20. Further, in the case of the bottom surface 50 shown in FIG. 6A, the width L of the bottom surface 50 in the Y-direction is equal across the direction (X-direction) intersecting the releasing direction. In other words, the shape of the second side 54 overlaps the first side 52 when translated in the Y-direction. The width L is preferably, for example, 0.5 mm or more and 5 mm or less.

In the case of the bottom surface 50 shown in FIG. 6B, the shape of the first side 52 is similar to the shape of the first side 52 shown in FIG. 4. In the case of the bottom surface 50 shown in FIG. 6B, the second side 54 has the protrusion 54b1, the protrusion 54b2, and the protrusion 54b3 protruding in a direction opposite to the releasing direction of the release tape 20 between an end 53a and an end 53b, and the end 53a and the end 53b are provided in a direction intersecting the releasing direction of the release tape 20. In addition, in the case of the bottom surface 50 shown in FIG. 6B, the shape of the second side 54 is line-symmetric with respect to a direction (X-direction) perpendicular to the releasing direction (Y-direction) of the release tape 20.

In the case of the bottom surface 50 shown in FIG. 6C, the shape of the first side 52 is similar to the shape of the first side 52 shown in FIG. 4. In the case of the bottom surface 50 shown in FIG. 6C, the second side 54 has the protrusion 54b1, the protrusion 54b2, and the protrusion 54b3 protruding in a direction opposite to the releasing direction of the release tape 20 between an end 53a and an end 53b, and the end 53a and the end 53b are provided in a direction intersecting the releasing direction of the release tape 20. In the case of the bottom surface 50 shown in FIG. 6C, the second side 54 has a sawtooth wave-like shape. Thus, the combination of the first side 52 and the second side 54 is not particularly limited. The first side 52 and the second side 54 described in this embodiment can all be combined into the bottom surface 50.

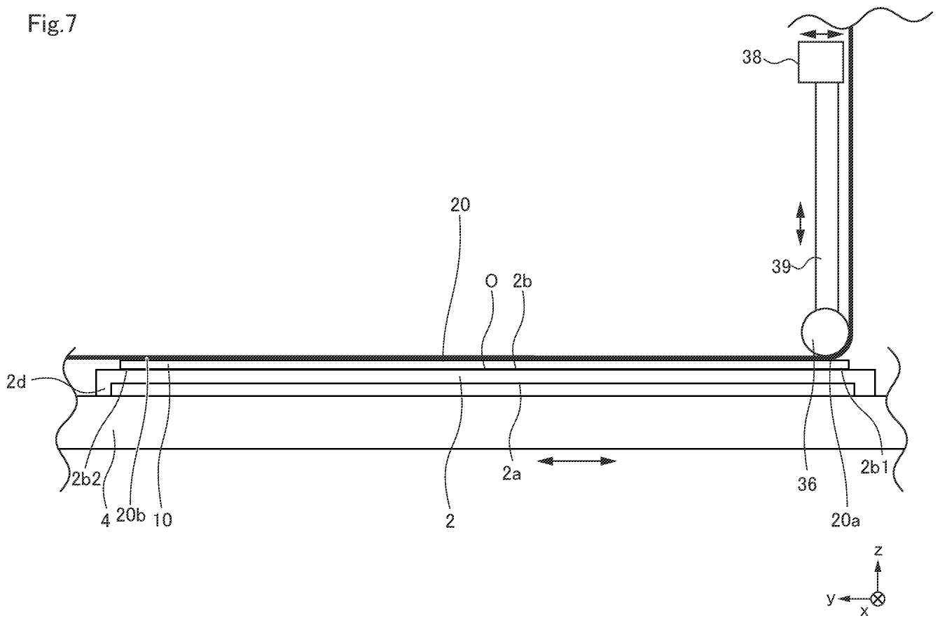

FIG. 7 to FIG. 10 are schematic diagrams for explaining the method for releasing the protective tape using the heat stamp according to the present embodiment. Note that in each of the drawings of FIG. 7 to FIG. 10, the illustration of a part of the member may be omitted.

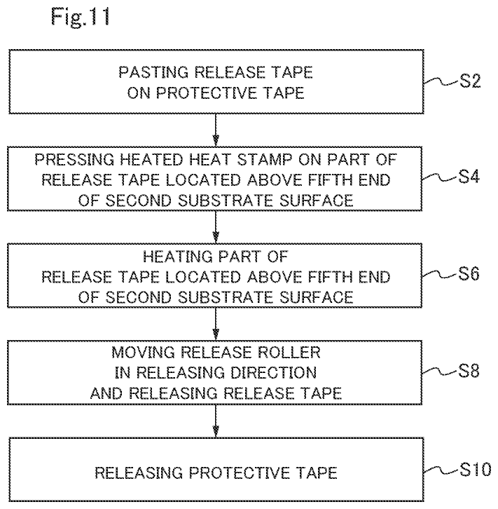

FIG. 11 is the flow chart of the method for releasing the protective tape using the heat stamp according to the first embodiment.

First, the release tape 20 is pasted on the protective tape 10 across the second substrate surface 2b using the paste roller 36 (S2 in FIG. 11 and FIG. 7).

Next, the bottom surface 50 of the heat stamp 100 heated by the heating device 90 is pressed on the part of the release tape 20 located above the fifth end 2b1 of the second substrate surface 2b (S4 in FIG. 11).

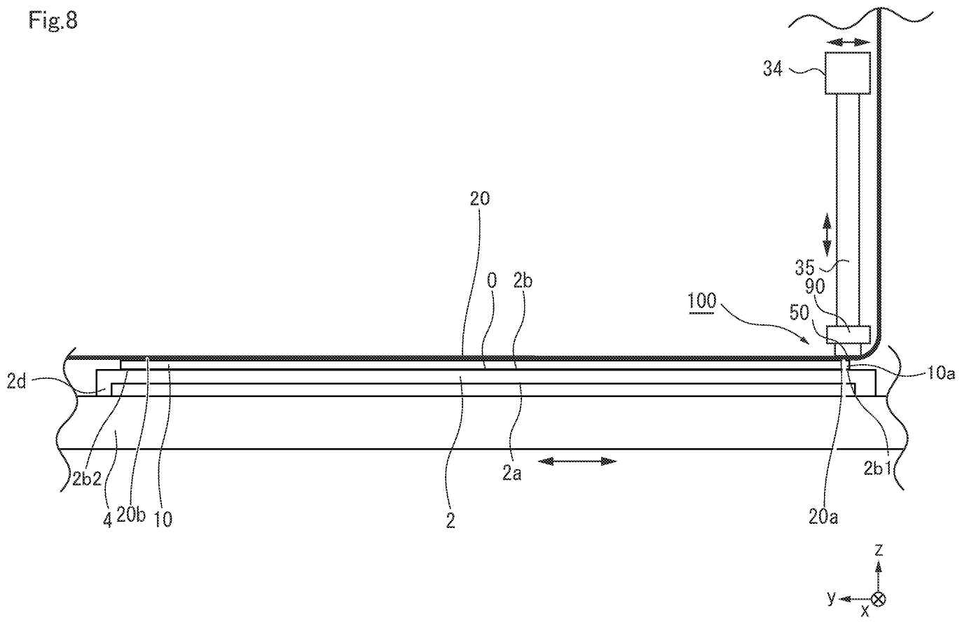

Next, using the bottom surface 50 of the heat stamp 100, the part of the release tape located above the fifth end 2b1 of the second substrate surface 2b is heated (S6 in FIG. 11 and FIG. 8).

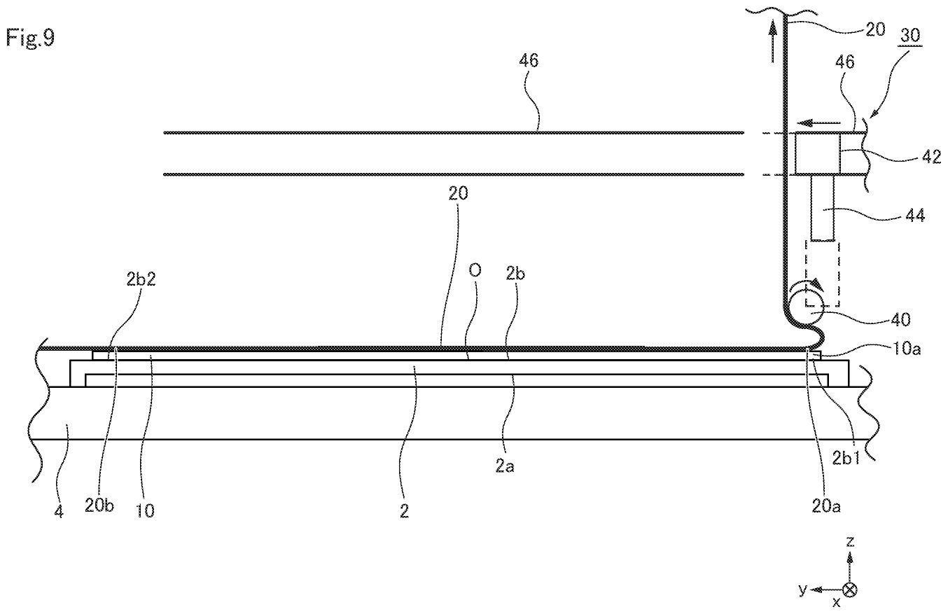

Next, the release roller 40 is contacted with the part of the release tape 20 located above the fifth end 2b1 of the second substrate surface 2b. Next, while the release the roller 40 is in contact, the release roller 40 is moved in the Y-direction parallel to the second substrate surface 2b from on the part of the release tape 20 located above the fifth end 2b1 of the second substrate surface 2b to on the release tape 20 located at or near the center O of the second substrate surface 2b so as to maintain a constant distance between the release roller 40 and the substrate 2, using the slider 42 and the rail 46. In this way, the release tape 20 is released from the part of the release tape 20 located above the fifth end 2b1 of the second substrate surface 2b. Here, it is preferable that the shape of the folding of the release tape 20 by the release roller 40 has a loop-like shape and is as constant as possible. In other words, the release roller 40 is moved in the Y-direction so that the shape of the folding of the release tape 20 by the release roller 40 is a loop-like shape as constant as possible. Here, the release roller 40 may move in the Y-direction with respect to the release tape 20. In addition, the release tape 20, the protective tape 10, the substrate 2, and the stage 4 may move in the −Y-direction with respect to the release roller 40, so that the release roller 40 may move in the Y-direction with respect to the release tape 20 (S8 of FIG. 11 and FIG. 9).

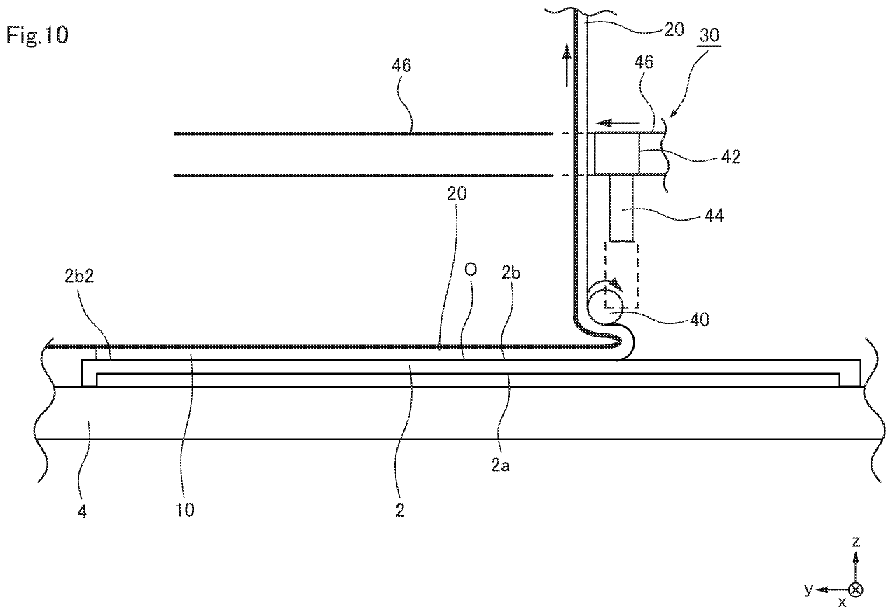

The release tape 20 is released from the second substrate surface 2b and the protective tape 10 is released from the second substrate surface 2b while the release tape 20 remains pasted and integrated to the protective tape 10 (FIG. 11 S10 and FIG. 10). Here, for example, the release roller 40 is rotated by winding the release tape 20 on a winding the roller (not shown). Thus, first, only the release tape 20 is delivered by the release roller 40. Then, after the protective tape 10 is released from the second substrate surface 2b, the protective tape 10 and the release tape 20 are integrated and sent by the release roller 40.

Next, functions and effects of the heat stamp and the method for releasing the protective tape using the heat stamp according to the present embodiment will be described.

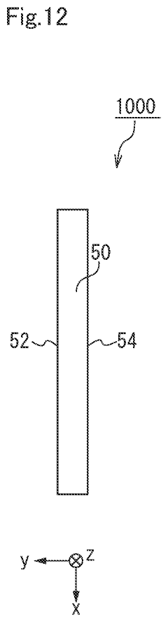

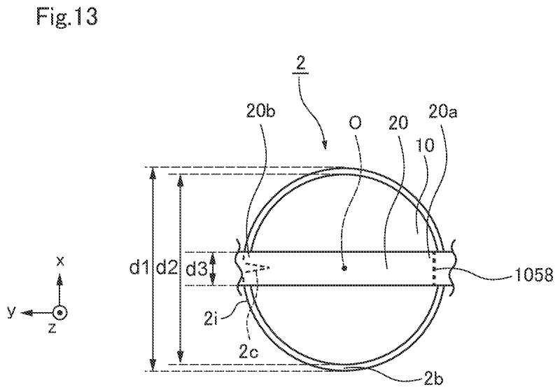

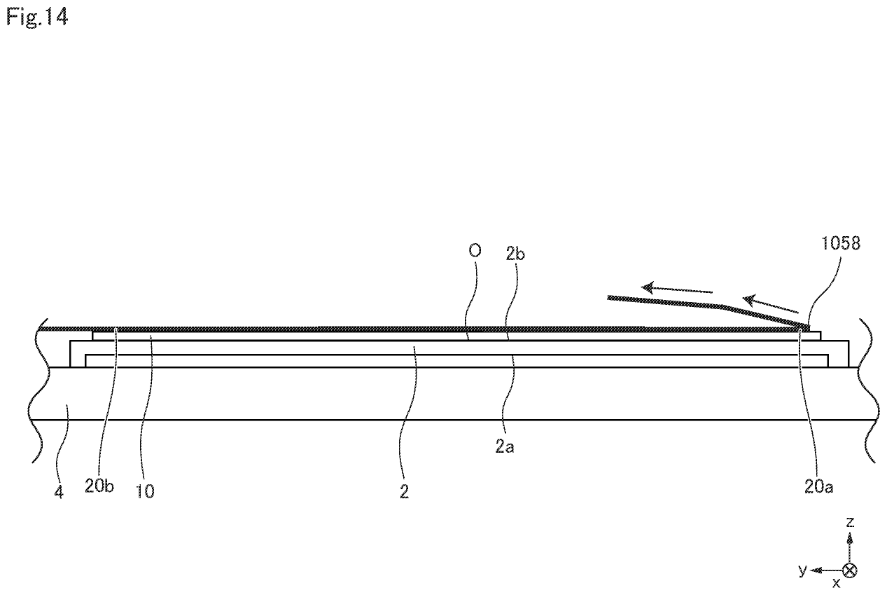

FIG. 12 is the schematic diagram of the heat stamp according to a comparative embodiment of the present embodiment. FIG. 13 and FIG. 14 are schematic diagrams of the method for releasing the protective tape using the heat stamp according to the comparative embodiment of the present embodiment.

The shape of the bottom surface 50 of the heat stamp 1000 shown in FIG. 12 is a rectangular shape. The first side 52 and the second side 54 are parallel to the X-direction. The first side 52 does not have the protrusion 52a.

When such the heat stamp 1000 is contacted with the third end 20a of the release tape 20, as shown in FIG. 13, the release tape 20 is formed with a straight line of a folding margin 1058 parallel to the X-direction, such as the folding margin 1058, reflecting the shape of the first side 52. When such the release tape 20 is released, as shown in FIG. 14, the release tape 20 is bent at an acute angle along the folding margin 1058, making it difficult to form a looped shape. Further, if the release tape 20 is to be released, the substrate 2 is detached from the stage 4, so that the release cannot be performed.

Therefore, the heat stamp 100 of the present embodiment has the protrusion 52a protruding in the releasing direction of the release tape 20 when the bottom surface 50 is pressed on the release tape 20.

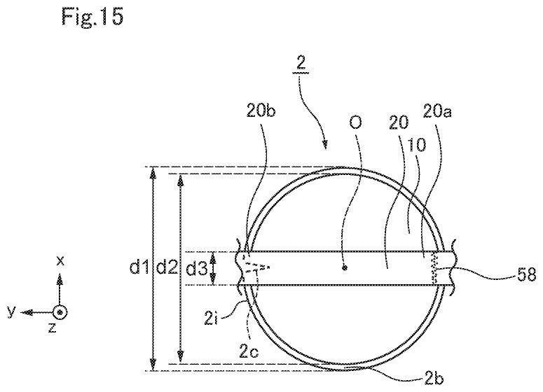

FIG. 15 is the schematic diagram for explaining the method for releasing the protective tape using the heat stamp according to the present embodiment. When the heat stamp 100 of the present embodiment is used, a non-linear folding margin 58 reflecting the shape of the protrusion 52a of the first side 52 is formed.

When the release tape 20 is released, a portion where adhesion is firmly performed and a portion where adhesion is not firmly performed are alternately provided in the X-direction. Therefore, while the adhesion between the protective tape 10 and the release tape 20 is maintained by the portion where the adhesion is firmly performed, the looped shape (FIG. 9) can be formed by the portion where the adhesion is not firmly performed. As a result, the release tape 20 is less likely to be bent at an acute angle.

In particular, since the first side 52 has a plurality of the protrusions, it is possible to finely provide a portion where adhesion is firmly performed and a portion where adhesion is not firmly performed. Therefore, the release tape 20 is less likely to be bent at an acute angle.

In providing the heat stamp as described above, it is preferable that the first side 52 has a rectangular wave shape or sawtooth wave-like shape, and that the shape of the first side 52 is curved in a direction opposite to the releasing direction.

When the width of the heat stamp in the releasing direction is constant in the direction intersecting the releasing direction, a portion where the bonding is firmly performed and a portion where the bonding is not firmly performed appear over a longer distance in the releasing direction. Therefore, the looped shape is likely to be formed over a longer distance in the releasing direction. In order to do so, it is more preferable to set the heat stamp to be 0.5 mm or more and 5 mm or less.

According to the heat stamp of the present embodiment, it is possible to provide the heat stamp capable of manufacturing a high-performance device. According to the protective tape releasing device using the heat stamp according to the present embodiment, it is possible to provide the protective tape releasing device using the heat stamp capable of manufacturing a high-performance semiconductor device.

### Second Embodiment

A heat stamp according to the present embodiment is the heat stamp used for releasing a protective tape from a substrate, the substrate including a first substrate surface, a second substrate surface provided opposite to the first substrate surface, the protective tape pasted on the second substrate surface, a release tape having a strip-like configuration, the release tape being pasted on the protective tape from above a fifth end of the second substrate surface to above a sixth end of the second substrate surface, the fifth end and the sixth end facing each other across the center of the second substrate surface, the heat stamp including: a plurality of bottom surfaces provided in a predetermined plane, wherein, when the bottom surfaces are pressed on the release tape, the bottom surfaces are provided separately from each other in a direction intersecting a releasing direction of the release tape, the releasing direction is parallel to a longitudinal direction of the strip-like configuration, and the releasing direction is from above the fifth end of the second substrate surface to above the sixth end of the second substrate surface. Here, description of the same content as that of the first embodiment is omitted.

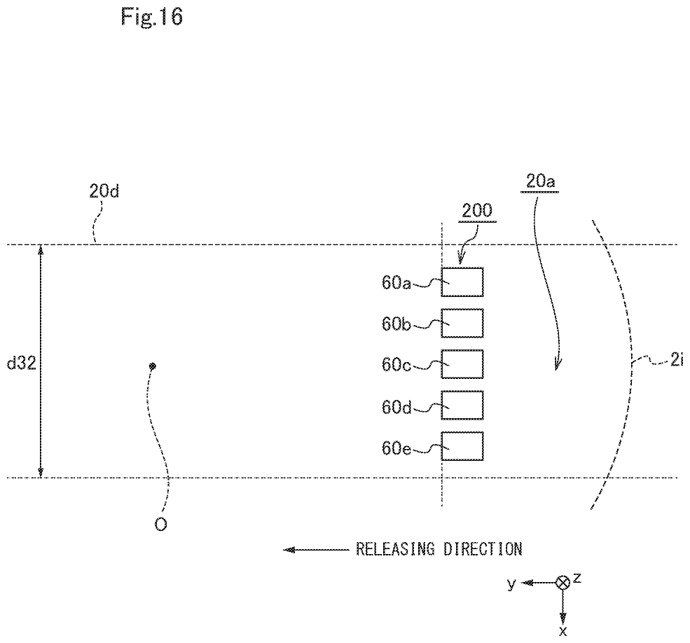

FIG. 16 is a schematic bottom view of the bottom surface 60 of the heat stamp 200 according to the second embodiment. A plurality of the bottom surfaces 60 are provided separately from each other in the X-direction. In FIG. 16, the bottom surface 60a, the bottom surface 60b, the bottom surface 60c, the bottom surface 60d and the bottom surface 60e are illustrated. The bottom surface 60 are connected to each other, for example, above the heat stamp 200 (not shown). The plurality of the bottom surfaces 60 are provided in a plane (an exemplary predetermined plane) parallel to the second substrate surface 2b.

The number of the bottom surfaces illustrated in FIG. 16 is five. However, the number of the bottom surfaces is not limited to five.

The shape of the bottom surface 60 is, for example, a rectangular shape. However, the shape of the bottom surface 60 is not limited to a rectangular shape.

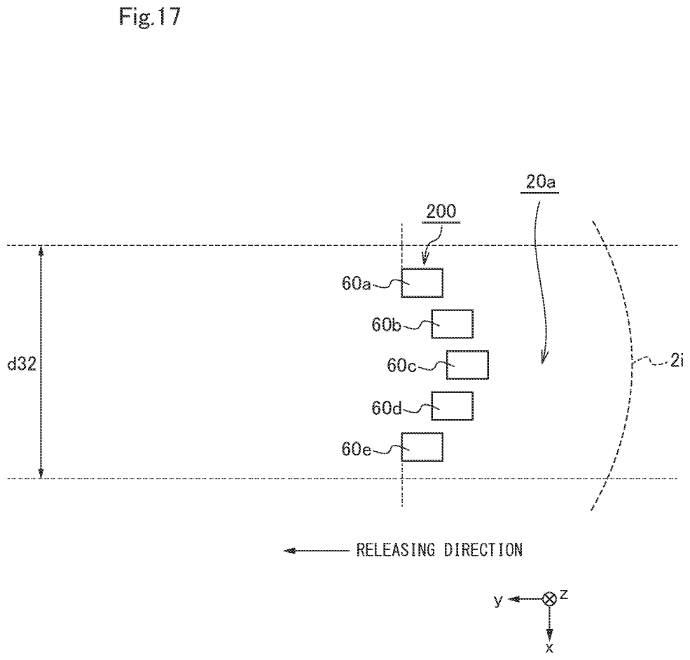

FIG. 17 is the schematic bottom diagram of the bottom surface of the heat stamp according to another aspect of the second embodiment.

In the X-direction, the bottom surface 60c (an example of the third bottom surface) is provided between the bottom surface 60b (an example of the first bottom surface) and the bottom surface 60d (an example of the second bottom surface). The bottom surface 60b and the bottom surface 60d protrude toward the releasing direction more than the bottom surface 60c. In addition, the bottom surface 60a protrudes toward the releasing direction more than the bottom surface 60b. In addition, the bottom surface 60c protrudes toward the releasing direction more than the bottom surface 60d. This is to smoothly release the release tape 20 and the protective tape 10 by arranging a plurality of the bottom surfaces 60 along the substrate edge 2i of the substrate 2.

According to the heat stamp of the present embodiment, it is possible to provide the heat stamp capable of manufacturing a high-performance device. According to the heat stamp based the protective tape stripping apparatus of the present embodiment, it is possible to provide the protective tape stripping apparatus using the heat stamp capable of manufacturing a high-performance semiconductor device.

While certain embodiments have been described, these embodiments have been presented by way of example only, and are not intended to limit the scope of the inventions. Indeed, the heat stamp and the method for releasing the protective tape using the heat stamp tape described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A heat stamp used for releasing a protective tape from a substrate,
the substrate including
a first substrate surface,
a second substrate surface provided opposite to the first substrate surface,
the protective tape pasted on the second substrate surface, and
a release tape having a strip-like configuration, the release tape being pasted on the protective tape from above a fifth end of the second substrate surface to above a sixth end of the second substrate surface, the fifth end and the sixth end facing each other across the center of the second substrate surface,
the heat stamp comprising:
a bottom surface having a first side, the first side being provided on a side of a releasing direction of the release tape, the releasing direction being parallel to a longitudinal direction of the strip-like configuration, and the releasing direction being from above the fifth end of the second substrate surface to above the sixth end of the second substrate surface,
wherein, when the bottom surface is pressed on the release tape, the first side has a protrusion protruding in the releasing direction of the release tape, the protrusion is provided between a first end of the first side and a second end of the first side, and the first end and the second end are provided separately from each other in a direction intersecting the releasing direction.

2. The heat stamp according to claim 1,
wherein the first side has a plurality of protrusions between the first end and the second end, and the protrusions protrude in the releasing direction of the release tape.

3. The heat stamp according to claim 2,
wherein the first side has a rectangular wave shape or a sawtooth wave-like shape.

4. The heat stamp according to claim 1,
wherein a shape of the first side is curved in a direction opposite to the releasing direction.

5. The heat stamp according to claim 2,
wherein a width of the bottom surface is equal across the direction intersecting the releasing direction.

6. The heat stamp according to claim 5,
wherein the width of the bottom surface in the releasing direction is 0.5 mm or more and 5 mm or less.

7. The heat stamp according to claim 1,
wherein the bottom surface has a second side provided on a side of a direction opposite to the releasing direction, and
wherein a shape of the second side is curved in a direction opposite to the releasing direction.

8. The heat stamp according to claim 2,
wherein the protrusions include a first protrusion, a second protrusion, and a third protrusion provided between the first protrusion and the second protrusion, and
the first protrusion and the second protrusion protrude toward the releasing direction more than the third protrusion.

9. A heat stamp used for releasing a protective tape from a substrate,
the substrate including
a first substrate surface,
a second substrate surface provided opposite to the first substrate surface,
the protective tape pasted on the second substrate surface,
a release tape having a strip-like configuration, the release tape being pasted on the protective tape from above a fifth end of the second substrate surface to above a sixth end of the second substrate surface, the fifth end and the sixth end facing each other across the center of the second substrate surface,
the heat stamp comprising:
a plurality of bottom surfaces provided in a predetermined plane,
wherein, when the bottom surfaces are pressed on the release tape, the bottom surfaces are provided separately from each other in a direction intersecting a releasing direction of the release tape, the releasing direction is parallel to a longitudinal direction of the strip-like configuration, and the releasing direction is from above the fifth end of the second substrate surface to above the sixth end of the second substrate surface.

10. The heat stamp according to claim 9,
wherein the bottom surfaces include a first bottom surface, a second bottom surface, and a third bottom surface provided between the first bottom surface and the second bottom surface, and
the first bottom surface and the second bottom surface protrude toward the releasing direction more than the third bottom surface.

11. A method for releasing the protective tape using the heat stamp according to claim 1, the method comprising:
a step of heating the heat stamp;
a step of heating a part of the release tape located above the fifth end of the second substrate surface by using the heat stamp;
a step of releasing the release tape from the part of the release tape located above the fifth end of the second substrate surface by moving a roller from above the fifth end of the second substrate surface, so as to maintain a constant distance between the roller and the substrate; and
a step of releasing the release tape and the protective tape from the second substrate surface.

12. The heat stamp according to claim 11,
wherein the first side has a plurality of protrusions between the first end and the second end, and the protrusions protrude in the releasing direction of the release tape.

13. The heat stamp according to claim 12,
wherein the first side has a rectangular wave shape or a sawtooth wave-like shape.

14. The heat stamp according to claim 11,
wherein the shape of the second side is curved in a direction opposite to the releasing direction.

15. The heat stamp according to claim 12,
wherein a width of the bottom surface is equal across the direction intersecting the releasing direction.

16. The heat stamp according to claim 15,
wherein the width of the bottom surface in the releasing direction is 0.5 mm or more and 5 mm or less.

17. The heat stamp according to claim 11,
wherein the bottom surface has a second side provided on the side of a direction opposite to the releasing direction, and
wherein the shape of the second side is curved in a direction opposite to the releasing direction.

18. The heat stamp according to claim 12,
wherein the protrusions include a first protrusion, a second protrusion, and a third protrusion provided between the first protrusion and the second protrusion, and
the first protrusion and the second protrusion protrude toward the releasing direction more than the third protrusion.

19. A method for releasing the protective tape using the heat stamp according to claim 9, the method comprising:
a step of heating the heat stamp;
a step of heating a part of the release tape located above the fifth end of the second substrate surface by using the heat stamp;
a step of releasing the release tape from the part of the release tape located above the fifth end of the second substrate surface by moving a roller from above the fifth end of the second substrate surface, so as to maintain a constant distance between the roller and the substrate; and
a step of releasing the release tape and the protective tape from the second substrate surface.

20. The method according to claim 19,
wherein the bottom surfaces include a first bottom surface, a second bottom surface, and a third bottom surface provided between the first bottom surface and the second bottom surface, and
the first bottom surface and the second bottom surface protrude toward the releasing direction more than the third bottom surface.
